(19) United States
(12) Patent Application Publication
(10) Pub. No.: US 2026/0327157 A1
(43) Pub. Date: Oct. 22, 2026

(54) CERAMIC COATING FOR COMPONENT

(71) Applicant: General Electric Company, Evendale, OH (US)

(72) Inventors: Hrishikesh Keshavan, Niskayuna, NY (US); Curtis Alan Johnson, Schenectady, NY (US); Geoffrey Mark Eadon, Ballston Spa, NY (US); Vidya Ramaswamy, La Canada, CA (US); Hongqiang Chen, Niskayuna, NY (US); Jaewon Moon, Flushing, NY (US); Jared Micheal Iverson, Amalga, UT (US); Nicholas Edward Antolino, Schenectady, NY (US); Bernard Patrick Bewlay, Niskayuna, NY (US); Ambarish Jayant Kulkarni, Glenville, NY (US)

(73) Assignee: General Electric Company, Evendale, OH (US)

(21) Appl. No.: 19/180,490

(22) Filed: Apr. 16, 2025

(51) Int. Cl. C04B 41/53; C04B 35/622

(52) U.S. Cl. CPC C04B 41/53; C04B 35/62222

(57) ABSTRACT

A component includes a substrate and a ceramic coating disposed on the substrate, the ceramic coating including a surface defining a vertical axis, wherein the ceramic coating comprises a plurality of non-intersecting sinuous slots defined from the surface, the plurality of non-intersecting sinuous slots including a first sinuous slot and a second sinuous slot adjacent to the first sinuous slot, wherein the first sinuous slot defines a plurality of first crests and a plurality of first troughs, wherein the second sinuous slot defines a plurality of second crests and a plurality of second troughs, and wherein each of the plurality of first troughs of the first sinuous slot aligns with an adjacent one of the plurality of second crests of the second sinuous slot.

### FIELD

The present disclosure relates to ceramic coatings (e.g., thermal barrier coatings and environmental barrier coatings) for components of turbomachinery, such as gas turbine engines.

### BACKGROUND

The design of modern gas turbine engines is driven by the demand for higher turbine efficiency. Ceramic matrix composites (“CMCs”) are an attractive material for turbine applications, as CMCs have high temperature capability and are light weight. CMC and metal components are often protected with an environmental barrier coating (“EBC”) and/or thermal barrier coatings (“TBC”) in turbine engine environments to avoid oxidation and recession in the presence of high temperature air flow.

### BRIEF DESCRIPTION OF THE DRAWINGS

A full and enabling disclosure of the present disclosure, including the best mode thereof, directed to one of ordinary skill in the art, is set forth in the specification, which makes reference to the appended figures, in which:

FIG. 1 is a cross-sectional schematic view of an exemplary component.

FIG. 2 is a top-down schematic view of a ceramic coating of an exemplary component.

FIG. 3 is a top-down schematic view of a ceramic coating of another exemplary component with sinusoidal slots.

FIG. 4 is a top-down schematic view of a ceramic coating of another exemplary component with sawtooth slots.

FIG. 5 is a top-down schematic view of a ceramic coating of another exemplary component with non-intersecting square slots.

FIGS. 6A-6D are top-down schematic views of ceramic coatings of other exemplary components with non-intersecting horizontal and vertical slots.

FIG. 7A is a schematic view of a non-planar surface and a projection onto a plane.

FIG. 7B is a schematic diagram of slots on the plane of FIG. 7A.

### DETAILED DESCRIPTION

Reference will now be made in detail to present embodiments of the disclosure, one or more examples of which are illustrated in the accompanying drawings. The detailed description uses numerical and letter designations to refer to features in the drawings. Like or similar designations in the drawings and description have been used to refer to like or similar parts of the disclosure.

The word “exemplary” is used herein to mean “serving as an example, instance, or illustration.” Any implementation described herein as “exemplary” is not necessarily to be construed as preferred or advantageous over other implementations. Additionally, unless specifically identified otherwise, all embodiments described herein should be considered exemplary.

The singular forms “a”, “an”, and “the” include plural references unless the context clearly dictates otherwise.

The term “at least one of” in the context of, e.g., “at least one of A, B, and C” refers to only A, only B, only C, or any combination of A, B, and C.

The phrases “from X to Y” and “between X and Y” each refers to a range of values inclusive of the endpoints (i.e., refers to a range of values that includes both X and Y).

As used herein, the terms “first,” “second,” “third,” and other ordinals are used to distinguish one component from another and are not intended to signify location or importance of the individual components.

The term “sinuous” means having a plurality of curves and/or turns, i.e., portions that change curvature and/or slope in a curved or straight manner.

In this context, a “grid” is a lattice of straight horizontal and vertical lines that form squares or rectangles. The term “grid-like” means a pattern that substantially approximates a grid without forming exact squares or rectangles.

The term “sinusoid” or “sinusoidal” refers to a curved sinuous shape similar to the mathematical sine and cosine functions, i.e., having a shape that extends vertically above and below a horizontal datum that is repeated periodically along a specified direction. A “sinusoidal pattern” may be defined mathematically by a sine or cosine function.

The term “sawtooth” means a sinuous shape with alternating rising and falling straight lines that form corners, similar to the teeth of a sawblade. The corners may be symmetric, such that the rising and falling lines have the same slope. Alternatively, the corners may be asymmetric, such that the rising and falling lines have different slopes. In addition, the corners may have sharp or rounded intersections.

The term “adjacent” means “immediately next to.” Two slots are “adjacent” to each other when no other similar slots or structures are disposed between the two slots.

A “planar” surface is a surface that is substantially flat, with few or no deviations from a mathematical plane. A “non-planar” surface includes a plurality of regions on the surface that are not flat, such as concave surfaces, convex surfaces, hyperbolic surfaces, wavy surfaces, jagged surfaces, etc.

The present disclosure is generally related to ceramic coatings for composite and metallic materials. Stresses experienced by the ceramic coatings may reduce the lifespan of components, particularly from crack formation and propagation. The strain tolerance of coatings (such as TBCs and EBCs) used in gas turbine engines is increased by the use of through-thickness pores and cracks within the ceramic coatings produced by air plasma spray (APS) methods and the use of columnar ceramic coatings produced by electron beam physical vapor deposition (EBPVD) methods. However, environmental dust, such as dust containing some combination of calcium-magnesium-alumino-silicate (CMAS), is often ingested into the hot sections of gas turbine engines. The dust can deposit on components in the engine and, due to the high surrounding temperatures, become molten. The resulting low-viscosity liquid infiltrates into the engineered pores and/or columns of the ceramic coatings on the component that protects the substrate. Once the liquid CMAS solidifies upon cooling, the compliance of the ceramic coatings and the strain tolerance capability of the coating decreases dramatically. Coating features needed for strain tolerance are filled by the solidified CMAS. Additionally, thermal stresses may induce cracks in the coatings and/or the coatings may delaminate from substrates.

When forming slots in the ceramic coatings, patterns that have intersecting slots may cause the slots to extend to a bond coat or a substrate at intersection points because some of the tools used to remove material from the ceramic coatings remove additional material at the intersection points. As an example, when the slots are removed with a laser, the laser residence time at the intersection points is greater, which results in a region with greater slot depth. These regions with less ceramic material may be prone to additional CMAS infiltration, higher thermal strains, and/or a lower hermiticity. In particular, when the component is subject to biaxial stresses, the lack of material at the intersection points may reduce the overall lifespan of the component.

By forming slots with non-intersecting patterns, the ceramic coating can mitigate biaxial stresses without intersection points that may breach into the bond coat or the substrate. In particular, non-intersecting sinuous slots can approximate the strain tolerance of a grid pattern of slots, which reduces biaxial stresses without reducing the durability of the ceramic coating. A tool such as laser can be programmed to form the non-intersecting patterns in the ceramic coating, such as with sinusoidal slots or sawtooth slots. Additionally, the non-intersecting pattern can be tailored for specific stress patterns, such as when stresses favor one direction over another. Such patterns may improve the overall lifespan of the component.

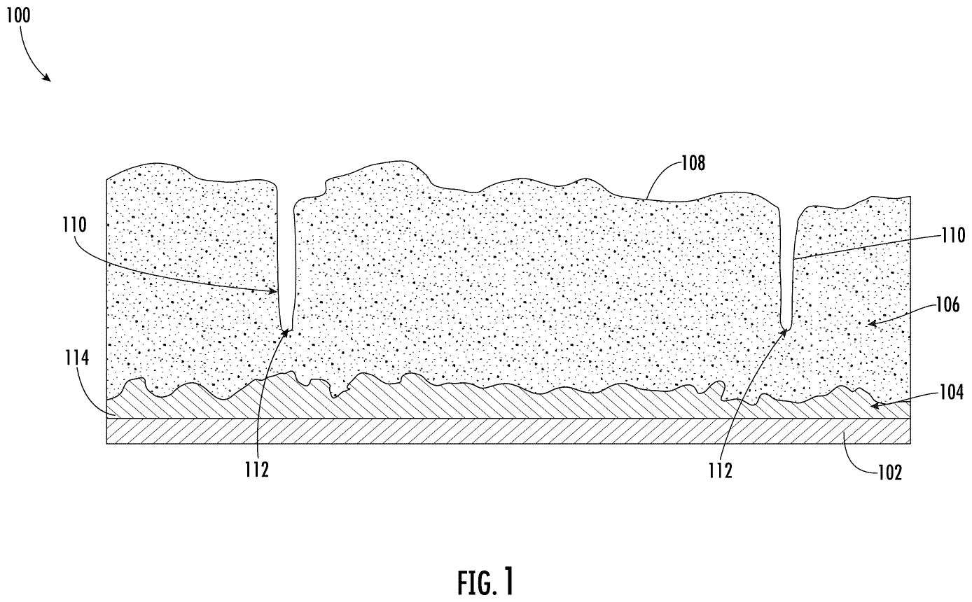

Referring now to the drawings, wherein identical numerals indicate the same elements throughout the figures, FIG. 1 is a cross-sectional view of an exemplary component 100. The component 100 includes a substrate 102, a bond coat 104, and a ceramic coating 106. The ceramic coating 106 includes a surface 108 and a plurality of slots 110 defined from the surface 108.

In particular, in the embodiment illustrated in FIG. 1, the ceramic coating 106 is one of a thermal barrier coating (TBC) or an environmental barrier coating (EBC). The ceramic coating 106 may include a single layer of TBC material or EBC material. However, in other embodiments, multiple layers may be utilized to form the ceramic coating 106. The slots may traverse the one or more layers of ceramic coating 106. The ceramic coating 106 may have a total thickness of about 100 microns to about 2500 microns, such as about 350 microns to about 700 microns.

As shown, a plurality of slots 110 are formed throughout the ceramic coating 106. In the embodiment illustrated in FIG. 1, the slots 110 extend from the surface 108 but do not extend to the bond coat 104. In particular, respective bottoms 112 of the slots 110 are disposed above an upper surface 114 of the substrate 102. The “bottom” 112 of a slot 110 is a point of the slot 110 farthest from the surface 108 in a vertical direction. Without wishing to be bound by any particular theory, it is believed that extending the slots 110 into the bond coat 104 or the substrate 102 may, under some circumstances, detract from component life.

In particular embodiments, the slots 110 extend through about 10% to about 90% of the total thickness of the ceramic coating 106, such as about 30% to about 90%, such as about 50% to about 90%. For example, if the total thickness of the ceramic coating 106 is about 1300 microns (about 50 mils), the depths of the slots 110 can be about 400 microns (about 15 mils) to about 1200 microns (about 45 mils). As another example, if the total thickness of the ceramic coating 106 is about 600 microns (about 24 mils), the depths of the slots 110 can be about 300 microns (about 12 mils) to about 540 microns (about 21 mils). As another example, if the total thickness of the ceramic coating 106 is about 125 microns (about 5 mils), the depths of the slots 110 can be about 12 microns (about 0.5 mils) to about 110 microns (about 4.5 mils).

The width of the slots 110 may be designed to be sufficiently large to maintain desirably low capillary forces and to reduce the risk of bridging the slots 110 with molten material, but small enough to not substantially affect the performance of the ceramic coating 106. For example, the slots 110 may be about 10 microns to about 200 microns wide, such as about 10 microns to about 100 microns wide, about 15 microns to about 90 microns wide, or about 20 microns to about 80 microns wide. For instance, the slots 110 may be about 25 microns wide to about 75 microns wide.

Additionally, the slots 110 may have a depth sufficient to reduce stresses in the ceramic coating 106 without exposing the substrate 102. For example, the slots 110 may have a depth of about 50 microns to about 1000 microns, such as about 100 microns to about 800 microns, or about 200 microns to about 700 microns. It will be appreciated that the depths of the slots 110 may be determined as a percentage of the thickness of the ceramic coating 106, such as from 10%-90% as described above. The aspect ratio (depth to width) of the slots 110 may be about 2 to about 50, such as about 3 to about 10, or about 5 to about 10. The slots 110 may be spaced about 0.25 mm to about 3 mm apart, such as about 0.5 mm to about 2 mm apart, or about 0.5 mm to about 1.5 mm apart. For instance, the slots 110 may be spaced about 1 mm apart. In general, the slots 110 may be spaced at distances based on the depths of the slots 110, as described above, such as from about 1 to about 8 times the depths of the slots 110, such as from about 2 to about 6 times the depths of the slots 110.

Various geometries of the slots 110 are available. In one embodiment, the slots 110 are parallel sided notches with an aspect ratio (depth/width) greater than 4 (e.g., about 4 to about 10). In another embodiment, the slots 110 may be of a V-shaped and/or U-shaped profile. It should be understood that the terms V-shaped and U-shaped describe the general geometry of the slots 110, while allowing for variations within the actual shape so as to not be a perfect V or U shape, respectively. The V-shape and/or U-shape may reduce the rate at which the closure of the slot 110 may occur due to CMAS build up, or CMAS reaction product such as Apatite forming on the sides of the slot 110 during operation.

A plurality of slots 110 may form an array of slots 110 traversing the ceramic coating 106, shown in further detail below. Each slot 110 may extend for the length of the surface 108 of the ceramic coating 106 (i.e., the entire length of the surface 108). In some embodiments, each slot 110 has a length that is about 1 cm or longer.

The ceramic coating 106 may be formed by any suitable process. For instance, one or more ceramic coatings 106 may be formed by air-plasma spray (APS), electron beam physical vapor deposition (EBPVD), high velocity oxygen fuel (HVOF), electrostatic spray assisted vapor deposition (ESAVD), direct vapor deposition, and deposition of ceramic powders via a slurry.

The bond coat 104 may be any suitable bond coat 104. For instance, in some embodiments, a platinum modified nickel aluminide bond coat 104 may be formed on the upper surface 114 of the substrate 102 and then a ceramic coating 106 may be applied to the platinum modified nickel aluminide bond coat 104. Without intending to be limiting, the bond coat 104 may help prevent or reduce oxidation of the substrate 102, thereby also reducing spallation. Other materials widely used for the bond coat 104 in CMC/EBC systems may include, but are not limited to, silicon, silica, silicates, silicides (e.g., a rare earth silicide such as molybdenum silicide or rhenium silicide, or mixtures thereof), mullite, or combinations thereof. That is, the bond coat 104 may be silicon-based, particularly for CMC-based substrates. As another example, the bond coat 104 may be a MCrAlY coat for Ni-based substrates.

The substrate 102 may be any suitable material such as a metal, such as steel or superalloys (e.g., nickel-based superalloys, cobalt-based superalloys, or iron-based superalloys, such as Rene N5, N500, N4, N2, IN718, Hastelloy X, or Haynes 188), a ceramic matrix composite, or other suitable materials for withstanding high temperatures. The ceramic coating 106 may be disposed along one or more portions of the substrate 102 or disposed substantially over the whole exterior of the substrate 102.

The slots 110 of FIG. 1 are shown substantially normal to the surface 108, i.e., extending at a substantially 90-degree angle from the surface 108. It will be appreciated that the slots 110 may be “tilted” relative to the surface 108, which means that the slots 110 define a different angle with the surface 108, such as 75 degrees, 60 degrees, 45 degrees, or another angle. Such titled slots 110 may be useful in 3-dimensional surfaces 108.

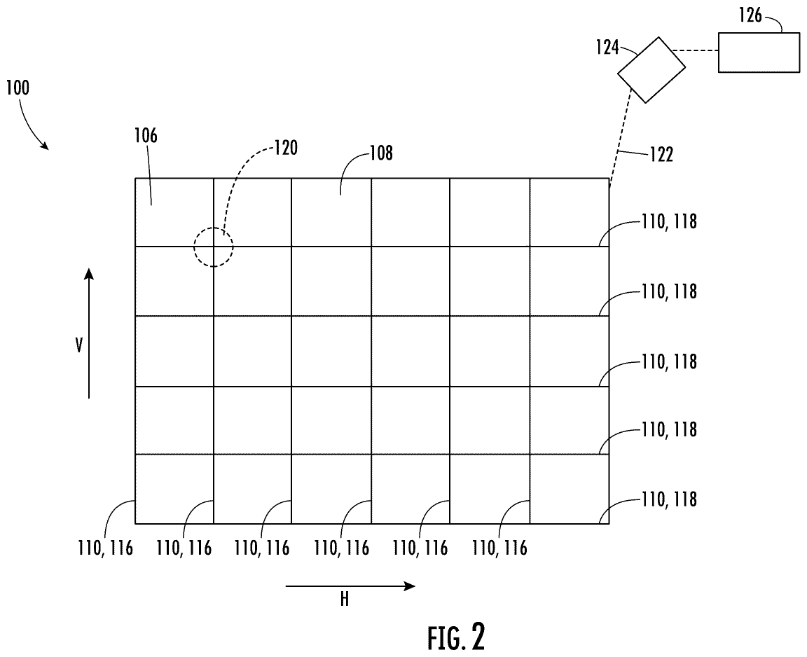

Now referring to FIG. 2, a top-down view of the component 100 is shown. The component 100 includes a ceramic coating 106, as described above. The ceramic coating 106 includes a surface 108 that defines a horizontal axis H and a vertical axis V.

The ceramic coating 106 of the component includes a plurality of slots 110 that form a grid. In particular, the plurality of slots 110 include a plurality of vertical slots 116 (i.e., slots substantially aligned with the vertical axis V) and a plurality of horizontal slots 118 (i.e., slots substantially aligned with the horizontal axis H). In this context, two objects are “aligned” with each other when a gap between the two objects along a specified direction or axis is within a specified threshold. For example, a slot 110 is aligned along the vertical axis V when the slot 110 deviates no more than 10% away from the vertical axis V, i.e., a gap between the slot 110 and a datum defining the vertical axis V is no more than 10% of a distance between two adjacent and parallel slots 110.

The vertical slots 116 intersect with the horizontal slots 118 at intersection points 120 of the grid, one of which is identified in FIG. 2. Each intersection point 120 is formed by a beam 122 from a laser 124 cutting one of the vertical slots 116 and one of the horizontal slots 118. A controller 126 directs the laser 124 to drive the beam 122 across the surface 108 of the ceramic coating 106 in a specific pattern. Because the beam 122 passes over the same location when forming the vertical slot 116 and the horizontal slot 118, more material is removed at the intersection point 120 than at other locations of the ceramic coating 106. That is, the depth of the intersection point 120 is greater than the depth of either the horizontal slot 118 or the vertical slot 116. This increased depth may reach the bond coat 104 such that no ceramic material remains at the intersection point 120, which can lead to debris and CMAS infiltration, lack of hermeticity, and/or fatigue-based damage to the component 100. The grid pattern improves strain tolerance and durability for the ceramic coating 106, particularly for components that have biaxial stresses. As such, it is desirable to have a pattern with the benefits of the grid but without the infiltration and loss of hermiticity at the intersection points 120.

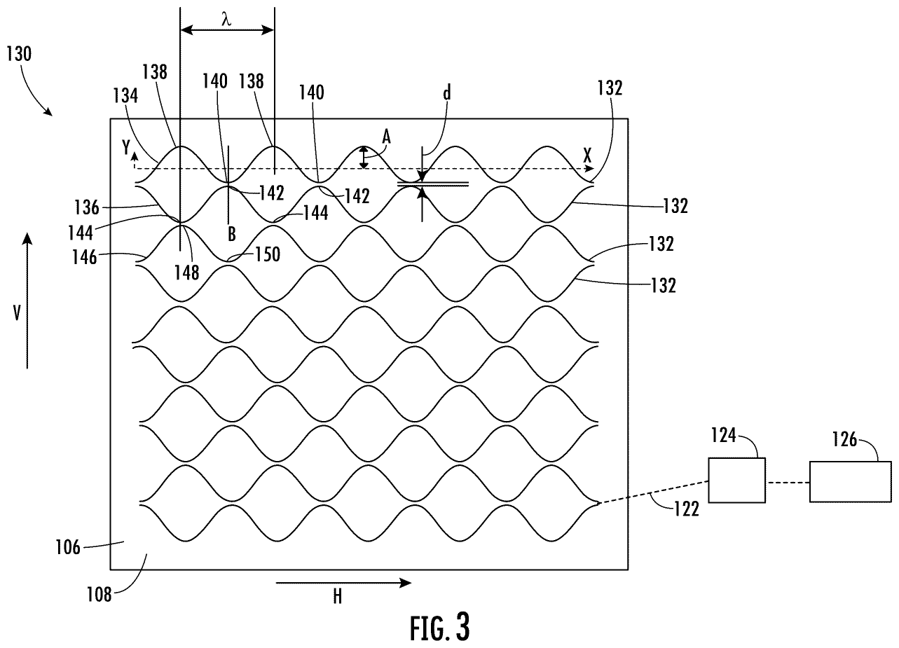

Now referring to FIG. 3, a top-down view of another component 130 is shown. It will be appreciated that similar components between the components 100, 130 will share similar numerals. A ceramic coating 106 of the component 130 includes a surface 108 defining a horizontal axis H and a vertical axis V. The ceramic coating 106 includes a plurality of non-intersecting sinuous slots 132 defined from the surface 108. That is, the sinuous slots 132 do not intersect each other, so no intersection points 120 are formed and the sinuous slots 132 do not reach the bond coat 104. In such a form, the plurality of non-intersecting sinuous slots 132 define a non-intersecting grid-like pattern. Each sinuous slot 132 defines a travel direction X and an amplitude direction Y, similar to a 2-dimensional waveform. The travel direction X is a direction along which a wave travels, and the amplitude direction Y is a direction of the size (or amplitude) of the wave. The amplitude direction Y is perpendicular to the travel direction X. Each sinuous slot 132 defines an amplitude A that is a distance from the axis of the travel direction X to a crest, such as one of the first crests 138.

In particular, the plurality of non-intersecting sinuous slots 132 include a first sinuous slot 134 and a second sinuous slot 136 adjacent to the first sinuous slot 134. The first sinuous slot 134 defines a sinuous shape including a plurality of waves, each of the plurality of waves including a first crest 138 and a first trough 140. In FIG. 3, the first sinuous slot 134 has a sinusoidal shape where adjacent first crests 138 and adjacent first troughs 140 are spaced by a specified wavelength λ to form a plurality of “periods.” Each period begins at one of the first crests 138 and ends at the next one of the first crests 138. In terms of a mathematical sinusoid, each period can be divided into 360 degrees of a sinusoidal wave, where each first crest 138 represents a value of 0 degrees and each first trough 140 represents a value of 180 degrees.

As with the first sinuous slot 134, the second sinuous slot 136 defines a sinusoidal shape. That is, the second sinuous slot 136 defines a sinuous shape having a plurality of second crests 142 and a plurality of second troughs 144 arranged in a plurality of periods. The second sinuous slot 136 is offset from the first sinuous slot 134 such that the first crests 138 of the first sinuous slot 134 are not aligned with the second crests 142 of the second sinuous slot 136. In particular, each of the plurality of first troughs 140 of the first sinuous slot 134 aligns with an adjacent one of the plurality of second crests 142 of the second sinuous slot 136, shown with the alignment datum B. Here, one of the first troughs 140 is considered “aligned” with one of second crests 142 when a distance along the travel direction X between the first trough 140 and the second crest 142 is below a specified threshold, such as 10% of the wavelength λ.

In terms of the sinusoidal shape, each period of the first sinuous slot 134 is shifted from each period of the second sinuous slot 136 by a specified amount of degrees; this shift is the “phase” difference between the first sinuous slot 134 and the second sinuous slot 136. In FIG. 3, the phase difference between the first sinuous slot 134 and the second sinuous slot 136 is approximately one half of the period, i.e., 180 degrees. By offsetting the first and second sinuous slots 134, 136 in this manner, the first and second sinuous slots 134, 136 form the non-intersecting grid-like pattern.

The plurality of non-intersecting sinuous slots 132 includes a third sinuous slot 146 adjacent to the second sinuous slot 136. The third sinuous slot 146 defines a sinusoidal shape including a plurality of third crests 148 and a plurality of third troughs 150 arranged in a plurality of periods. The third sinuous slot 146 is shifted by 180 degrees relative to the second sinuous slot 136 such that each of the plurality of second troughs 144 aligns with an adjacent one of the plurality of third crests 148. In such a form, the third sinuous slot 146 has no phase difference with the first sinuous slot 134, such that each of the plurality of third crests 148 align with a respective one of the plurality of first crests 138, and each of the plurality of third troughs 150 align with a respective one of the plurality of first troughs 140. It will be appreciated that the plurality of sinuous slots 132 are arranged in such a manner, where adjacent sinuous slots 132 are out of phase with each other by 180 degrees, and alternating ones of the sinuous slots 132 are aligned with each other in phase. This arrangement of 180 degree shifts in phase between adjacent sinuous slots 132 defines the non-intersecting grid-like pattern.

The first and second sinuous slots 134, 136 are arranged close to each other without intersecting. In particular, each of the plurality of first troughs 140 is disposed from the adjacent one of the plurality of second crests 142 a distance d in a range from 50 to 1000 microns, such as from 50 to 150 microns. Typically, as described above, a width of one of the sinuous slots 132 is in a range from 25 to 75 microns, and the distance d between the first troughs 140 and the second crests 142 may be at least 2 times the slot width. Additionally, the wavelength λ of the first and second sinuous slots 134, 136 is in a range from 0.5 times to 20 times of the depth of the first and second sinuous slots 134, 136. The ratio of the amplitude A to the wavelength λ may be in a range from 1:64 to 4:1, such as 1:32 to 2:1, such as 1:16 to 1:1, such as 1:8 to 1:2, such as 1:4. It will be appreciated that the wavelength λ and/or the amplitude A may vary in the travel direction X, particularly when the surface 108 is non-planar.

The sinuous slots 132 may be formed in the ceramic coating 106 with a laser 124. It will be appreciated that the sinuous slots 132 may be formed by another material removal method, such as electron beam milling, ultrasonic milling, imprinting, etching, or combinations thereof. More specifically, a controller 126 actuates the laser 124 to emit a beam 122 to remove the first sinuous slot 134 from the surface 108 of the ceramic coating 106. The controller 126 instructs the laser 124 to move the beam 122 along a sinuous pattern to form the sinuous shape of the first sinuous slot 134. The sinuous pattern may be a first sinusoidal path having a specified phase. That is, the controller 126 may include a memory that stores a mathematical model of the first sinusoidal path as a sinusoidal curve with a specific amplitude, wavelength, and phase, and the 124 moves the beam 122 according to the modeled sinusoidal curve.

The controller 126 actuates the laser 124 to emit the beam 122 to remove the second sinuous slot 136 from the surface 108 of the ceramic coating 106. The laser 124 moves the beam 122 along a second sinusoidal path with a different phase than the first sinusoidal path such that the second sinuous slot 136 is spaced from the first sinuous slot 134 in a non-intersecting manner. Moreover, the second sinusoidal path positions the second sinuous slot 136 to be shifted horizontally from the first sinuous slot 134. It will be appreciated that the second sinuous slot 136 defines a same sinuous shape as the first sinuous slot 134 but shifted horizontally. That is, the second sinusoidal path is mathematically modelled as the same amplitude and wavelength as the sinusoidal path, but the phase differs from the sinusoidal path by 180 degrees. The controller 126 then actuates the laser 124 to remove a plurality of sinuous slots 132 from the surface 108 of the ceramic coating 106 to form a non-intersecting pattern, such as a non-intersecting grid. In particular, the laser may form the sinuous slots 132 by alternating between the first sinusoidal path and the second sinusoidal path for successive slots, thereby forming a grid-like pattern. While the sinuous slots 132 of FIG. 3 are shown to have a same amplitude and wavelength as each other of the sinuous slots 132, it will be appreciated that some of the sinuous slots 132 may differ in amplitude, wavelength, and/or spacing along the sinusoidal path.

As described above, the first sinuous slot 134 is spaced above the upper surface 114 of the substrate 102, and the second sinuous slot 136 is spaced above the upper surface 114 of the substrate 102. That is, the controller 126 actuates the laser 124 to remove the first sinuous slot 134 by removing material to a depth that is above an upper surface 114 of the substrate, as shown in FIG. 1. Because the sinuous slots 132 do not intersect, the laser 124 does not produce any intersection points 120 where the beam 122 may remove material from the bond coat 104 or the substrate 102.

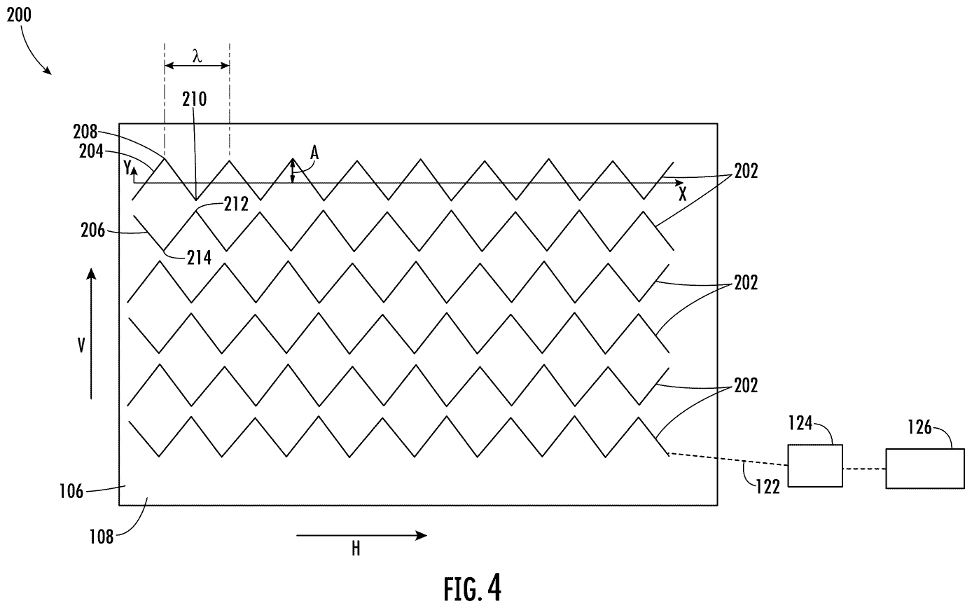

With reference to FIG. 4, a top-down view of another component 200 is shown. The component 200 includes a ceramic coating 106 having a surface 108. The component 200 includes a plurality of sinuous slots 202, each sinuous slot 202 having a sawtooth shape. As with the component 130 of FIG. 3, the component 200 includes a first sinuous slot 204 and a second sinuous slot 206, the second sinuous slot 206 shifted horizontally relative to the first sinuous slot 204. That is, the first sinuous slot 204 has a plurality of first crests 208 and a plurality of first troughs 210, and the second sinuous slot 206 has a plurality of second crests 212 and a plurality of second troughs 214. The first troughs 210 are aligned with the second crests 212 to form a non-intersecting pattern, such as a non-intersecting grid.

To form the plurality of sinuous slots 202, a controller 126 actuates a laser 124 to emit a beam 122 along a first sawtooth path having a first phase to form the first sinuous slot 202. As with the sinusoidal paths of FIG. 3, the first sawtooth path has a specific amplitude, wavelength, and phase. Then, the controller 126 actuates the laser 124 to emit the beam 122 along a second sawtooth path that has a same amplitude and wavelength as the first sawtooth path, but the second sawtooth path has a second phase that differs from the first phase by approximately 180 degrees. The controller 126 may actuate the laser 124 to form a plurality of sinuous slots, each successive sinuous slot 202 alternating between the first sawtooth path and the second sawtooth path to form a grid-like pattern.

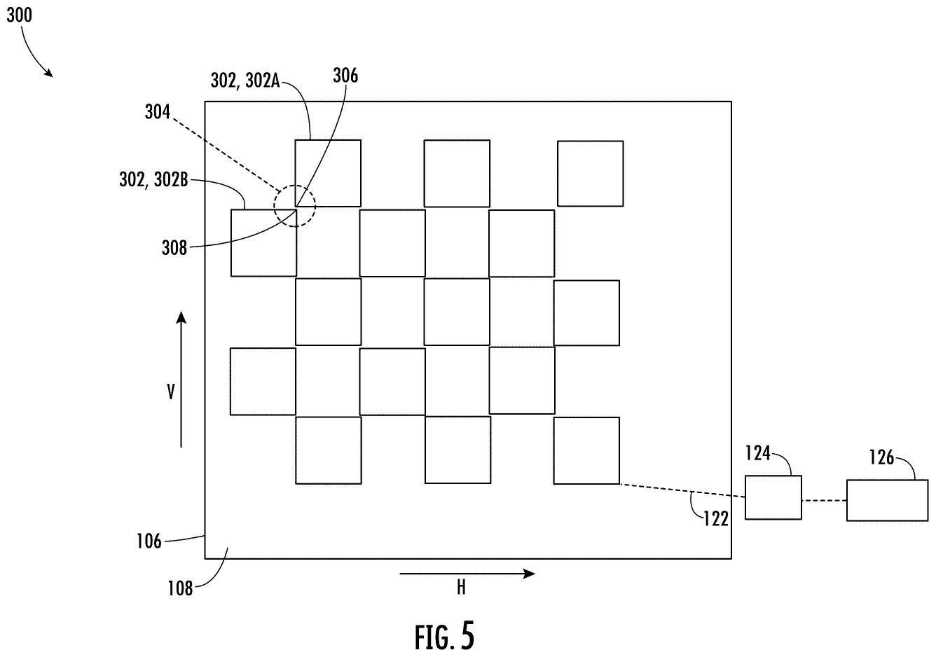

With reference to FIG. 5, a top-down view of another component 300 is shown. The component 300 includes a plurality of square-shaped slots 302 formed from a surface 108 of a ceramic coating 106, each square-shaped slot 302 spaced from each other square shaped slot 302. That is, unlike the grid pattern of FIG. 2, the slots 302 do not intersect each other. As shown in the region 304, a first corner 306 of a first slot 302A is spaced from a second corner 308 of an adjacent second slot 302B. A controller 126 actuates a laser 124 to emit a beam 122 to remove material from the surface 108 of the ceramic coating 106 to form one of the square-shaped slots 302, ceases operation of the laser 124, and the actuates the laser 124 to remove material from the surface 108 of the ceramic coating 106 to form another of the square-shaped slots 302. By ceasing operation of the laser 124 between formation of each successive square-shaped slot 302, the slots 302 are disconnected from each other, and no intersection points form. In such a manner, each of the square-shaped slots 302 terminates above a bond coat 104 of the component 300.

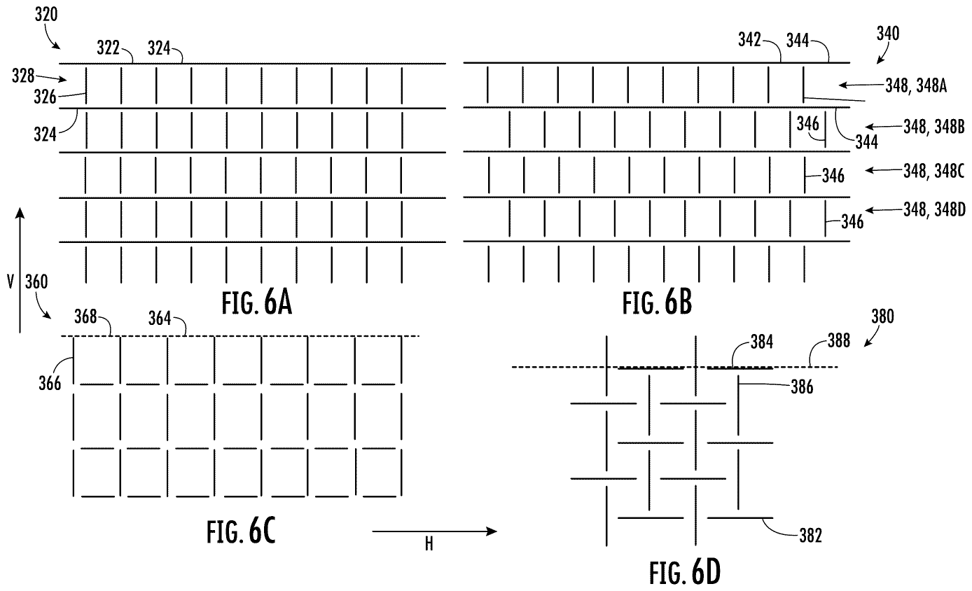

Now referring to FIGS. 6A-6D, other non-intersecting patterns for slots of components are shown. Each of the patterns is formed from non-intersecting horizontal and vertical slots. FIG. 6A shows a component 320 with a pattern of non-intersecting slots 322 that are vertically aligned. FIG. 6B shows a component 340 with a pattern of non-intersecting slots 342 that are horizontally staggered. FIG. 6C shows a component 360 with a grid-like pattern of non-intersecting slots 362 with no corners. FIG. 6D shows a component 380 with a grid-like weaved pattern of non-intersecting slots 382.

With reference to FIG. 6A, the non-intersecting slots 322 include a plurality of horizontal slots 324 and a plurality of vertical slots 326. The horizontal slots 324 extend continuously along a surface 108 of a ceramic coating 106. The vertical slots 326 terminate prior to reaching the horizontal slots 324 such that the vertical slots 326 and the horizontal slots 324 do not intersect. The vertical slots 326 align along the vertical axis V. In such a form, a controller 126 (FIG. 2) actuates a laser 124 (FIG. 2) to emit a beam 122 (FIG. 2) to form the vertical slots 326 along a single vertical position, ceasing operation of the laser 124 when the vertical slots 326 are within a specified distance from each horizontal slot 324. Thus, the laser 124 can form the vertical slots 326 in fewer vertical movements while still forming a non-intersecting pattern. A lane 328 is defined between two adjacent horizontal slots 324, and the vertical slots 326 are contained within each lane 328. The vertical slots 326 are evenly spaced from each other in along the horizontal axis H in each lane 328.

With reference to FIG. 6B, the non-intersecting slots 342 include a plurality of horizontal slots 344 and a plurality of vertical slots 346. The horizontal slots 344 extend continuously along a surface 108 of a ceramic coating 106. The vertical slots 346 are staggered horizontally from each other. That is, a lane 348 is defined between two adjacent horizontal slots 344, and the vertical slots 346 within each lane 348 are spaced evenly from each other. The vertical slots 346 of adjacent lanes 348 are horizontally staggered from each other, while the vertical slots 346 of alternating lanes 348 are vertically aligned with each other. For example, the vertical slots 346 in a first lane 348A and a third lane 348C are vertically aligned with each other, and the vertical slots 346 in a second lane 348B and a fourth lane 348D are vertically aligned with each other, but the vertical slots 346 of the second lane 348B are horizontally staggered from the vertical slots 346 of the first lane 348A. Staggering the vertical slots 346 provides non-intersecting slots and improves dissipation of biaxial stresses by reducing concentration of stresses in the vertical direction.

With reference to FIG. 6C, the non-intersecting slots 362 include a plurality of horizontal slots 364 and a plurality of vertical slots 366 formed on the surface 108 of the ceramic coating 106 in a non-intersecting grid-like pattern. More specifically, the horizontal slots 364 extend in along the horizontal axis H and terminate prior to meeting one of the vertical slots 366. The vertical slots 366 extend along the vertical axis V and terminate prior to meeting one of the horizontal slots 364. That is, the horizontal slots 364 and the vertical slots 366 are formed by the laser 124 (FIG. 2) in a grid-like pattern, but the laser 124 ceases operation where the horizontal slots 364 and the vertical slots 366 would intersect. As an example, some of the horizontal slots 364 extend along a horizontal datum 368, and some of the vertical slots 366 extend along the vertical axis V toward the horizontal datum 368. The horizontal slots 364 terminate prior to the locations where the vertical slots 366 meet the horizontal datum 368 and begin after the locations where the vertical slots 366 meet the horizontal datum 368. In such a form, the pattern is substantially a grid but without intersecting slots.

With reference to FIG. 6D, the non-intersecting slots 382 include a plurality of horizontal slots 384 and a plurality of vertical slots 386 formed on the surface 108 of the ceramic coating 106 in a non-intersecting grid-like weaved pattern. As with the pattern of FIG. 6C, the horizontal slots 384 extend along a horizontal datum 388. The vertical slots 386 extend across the horizontal datum 388 but do not intersect the horizontal slots 384. Arranging the horizontal slots 384 and the vertical slots 386 in such a weaved pattern improves dissipation of biaxial stresses by reducing concentration of stresses along the vertical axis V.

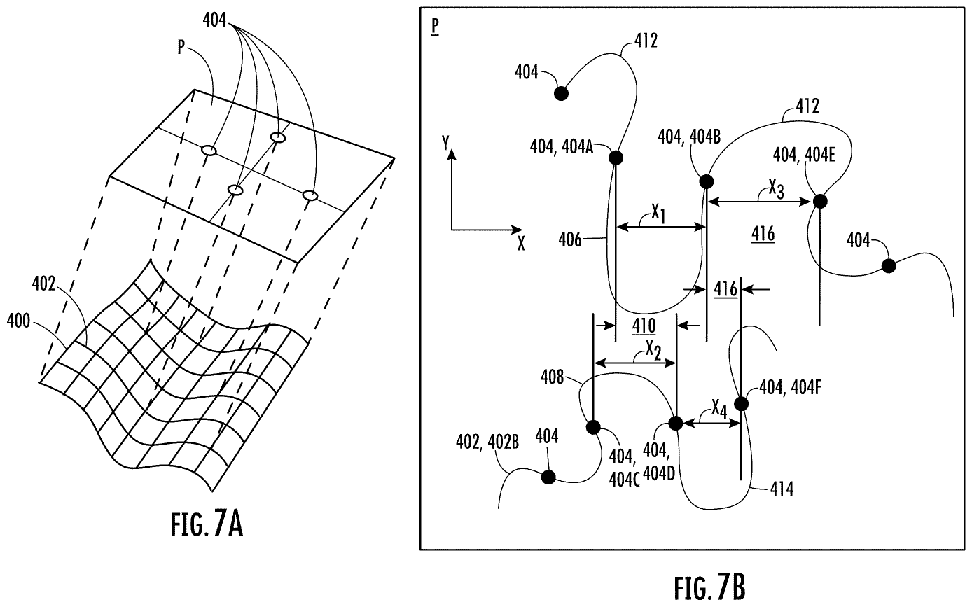

Now referring to FIGS. 7A-7B, schematic views of slots on a non-planar surface 400 are shown, such as a three-dimensional curved or wavy surface. FIG. 7A is a view of the non-planar surface 400 and a projection onto a plane P. FIG. 7B is a view of slots 402 on the plane P.

Referring to FIG. 7A, it will be appreciated that slots 402 may be formed in a surface 400 that is not flat or rectangular, such as on a torus, an annulus, or an airfoil-like shape. In such a form, while the slots 402 do not intersect, alignment of portions of the slots 402 may be determined differently than on a flat, rectangular surface (such as those of FIGS. 2-6D). To align slots 402 on the non-planar surface 400, the slots 402 may be projected onto a plane P. The slots 402 define inflection points 404 where a curvature of the slot 402 changes sign, i.e., changes from positive to negative or from negative to positive. The inflection points 404 are projected onto the plane P to determine alignment of the slots 402, as described below.

Now referring to FIG. 7B, the slots 402 in the plane P are shown. As described above, the slots 402 define a travel direction X and an amplitude direction Y. The inflection points 404 define portions of the slots 402 that may correspond to crests and troughs of a sinusoid. In particular, two consecutive inflection points 404 define a portion of the slot 402 that has a curvature of the same sign. In FIG. 7B, a first portion 406 of a first slot 402A is defined by inflection points 404A, 404B, and a second portion 408 of a second slot 402B is defined by inflection points 404C, 404D.

The first portion 406 defines a length X₁ in the travel direction X, which is the distance in the travel direction X between the inflection points 404A, 404B. The second portion 408 similarly defines a length X₂. A first alignment zone 410 is the distance along the travel direction X that includes both lengths X₁, X₂. That is, the first alignment zone 410 is the region where the first portion 406 and the second portion 408 overlap in the travel direction X. The slots 402A, 402B may be “aligned” when the first alignment zone 410 is a specified percentage of either of the lengths X₁, X₂, such as 75-90% of the shorter of the lengths X₁, X₂. Because the first portion 406 and the second portion 408 curve toward each other, the first alignment zone 410 may also be referred to as a “proximal” alignment zone 410.

The first slot 402A defines a third portion 412 between inflection points 404B and 404E, and the second slot 402B defines a fourth portion 414 between inflection points 404D and 404F. The third portion 412 defines a length X₃, and the fourth portion 414 defines a length X₄. A second alignment zone 416 is the region where the third portion 412 and the fourth portion 414 overlap in the travel direction X, i.e., the region that includes both lengths X₃, X₄. Because the third portion 412 and the fourth portion 414 curve away from each other, the second alignment zone 416 may also be referred to as a “distal” alignment zone 416. Alignment of the slots 402A, 402B may be determined by a specified amount of proximal and distal alignment zones 410, 416 along the entirety of the slots 402A, 402B and/or a percentage of a total length of the slots 402A, 402B that includes the alignment zones 410, 416. As an example, the slots 402A, 402B may be “aligned” when the combined lengths of the alignment zones 410, 416 is at least 75% of the total length of the slots 402A, 402B. By projecting the slots 402A, 402B from the non-planar surface 400 to the plane P, this metric for alignment may be used to reduce thermal stresses in the ceramic coating.

Further aspects are provided by the subject matter of the following clauses:

A component includes a substrate and a ceramic coating disposed on the substrate, the ceramic coating including a surface, wherein the ceramic coating includes a plurality of non-intersecting sinuous slots defined from the surface, the plurality of non-intersecting sinuous slots including a first sinuous slot and a second sinuous slot adjacent to the first sinuous slot, wherein the first sinuous slot defines a plurality of first crests and a plurality of first troughs, wherein the second sinuous slot defines a plurality of second crests and a plurality of second troughs, and wherein at least one of the plurality of first troughs of the first sinuous slot aligns with an adjacent one of the plurality of second crests of the second sinuous slot.

The component of any of the preceding clauses, wherein each of the plurality of first troughs is disposed from the adjacent one of the plurality of second crests a distance from 50 to 1000 microns.

The component of any of the preceding clauses, wherein the first sinuous slot has a sinusoidal shape.

The component of any of the preceding clauses, wherein the first sinuous slot has a sawtooth shape.

The component of any of the preceding clauses, wherein the plurality of non-intersecting sinuous slots includes a third sinuous slot adjacent to the second sinuous slot, the third sinuous slot including a plurality of third crests and a plurality of third troughs, wherein each of the plurality of second troughs aligns with an adjacent one of the plurality of third crests.

The component of any of the preceding clauses, wherein each of the plurality of third crests align with a respective one of the plurality of first crests, and each of the plurality of third troughs align with a respective one of the plurality of first troughs.

The component of any of the preceding clauses, wherein the plurality of non-intersecting sinuous slots define a non-intersecting pattern.

The component of any of the preceding clauses, wherein the first sinuous slot defines a sinuous shape including a plurality of waves, each of the plurality of waves including one of the plurality of first crests and one of the plurality of first troughs.

The component of any of the preceding clauses, wherein the first sinuous slot defines a depth in a range from 100 microns to 1100 microns.

The component of any of the preceding clauses, wherein the first sinuous slot defines an amplitude and a wavelength, and a ratio of the amplitude to the wavelength is in a range from 1:64 to 4:1.

The component of any of the preceding clauses, wherein the slots extend through about 10% to about 90% of the total thickness of the ceramic coating.

A method of forming a ceramic coating for a component, the method including laying the ceramic coating on a substrate of the component, removing a first sinuous slot from a surface of the ceramic coating, the first sinuous slot defining a sinuous shape, the sinuous shape defining a travel direction and an amplitude direction, and removing a second sinuous slot from the surface of the ceramic coating such that the second sinuous slot is spaced from the first sinuous slot in a non-intersecting manner, the second sinuous slot defining a second sinuous shape, wherein the second sinuous slot is shifted along the travel direction from the first sinuous slot.

The method of any of the preceding clauses, wherein the sinuous shape includes a plurality of waves, each wave including a crest and a trough, wherein the respective troughs of the plurality of waves of the first sinuous slot align with the respective crests of the plurality of waves of the second sinuous slot.

The method of any of the preceding clauses, wherein removing the first sinuous slot further includes moving a laser along a first sinusoidal path having a first phase, wherein removing the second sinuous slot further includes moving the laser along a second sinusoidal path having a second phase, wherein the second phase differs from the first phase by 180 degrees.

The method of any of the preceding clauses, wherein the first sinusoidal path and the second sinusoidal path each have a same wavelength.

The method of any of the preceding clauses, wherein removing the first sinuous slot further includes moving the laser along a first sawtooth path having a first phase, wherein actuating the laser to remove the second sinuous slot further includes moving the laser along a second sawtooth path having a second phase, wherein the second phase differs from the first phase by 180 degrees.

The method of any of the preceding clauses, wherein the sinuous shape is a different shape than the second sinuous shape.

The method of any of the preceding clauses, wherein the sinuous shape and the second sinuous shape are a same shape.

The method of any of the preceding clauses, further including removing a plurality of sinuous slots from the surface of the ceramic coating to form a non-intersecting pattern.

A ceramic coating for a component, the ceramic coating including a surface defining a vertical axis and a horizontal axis, and a plurality of non-intersecting sinuous slots defined in the surface, the plurality of non-intersecting sinuous slots including a first sinuous slot and a second sinuous slot adjacent to the first sinuous slot, wherein the first sinuous slot defines a plurality of first crests and a plurality of first troughs, wherein the second sinuous slot defines a plurality of second crests and a plurality of second troughs, wherein each of the plurality of first troughs of the first sinuous slot aligns with an adjacent one of the plurality of second crests of the second sinuous slot along the vertical axis.

The ceramic coating of any of the preceding clauses, wherein the plurality of non-intersecting sinuous slots includes a third sinuous slot adjacent to the second sinuous slot, the third sinuous slot including a plurality of third crests and a plurality of third troughs, wherein each of the plurality of second troughs aligns with an adjacent one of the plurality of third crests along the vertical axis.

The ceramic coating of any of the preceding clauses, wherein the first sinuous slot has a sinusoidal shape.

The ceramic coating of any of the preceding clauses, wherein the first sinuous slot has a sawtooth shape.

This written description uses examples to disclose the present disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A component comprising:
a substrate; and
a ceramic coating disposed on the substrate, the ceramic coating including a surface,
wherein the ceramic coating comprises a plurality of non-intersecting sinuous slots defined from the surface, the plurality of non-intersecting sinuous slots including a first sinuous slot and a second sinuous slot adjacent to the first sinuous slot,
wherein the first sinuous slot defines a plurality of first crests and a plurality of first troughs,
wherein the second sinuous slot defines a plurality of second crests and a plurality of second troughs, and
wherein at least one of the plurality of first troughs of the first sinuous slot aligns with an adjacent one of the plurality of second crests of the second sinuous slot.

2. The component of claim 1, wherein each of the plurality of first troughs is disposed from the adjacent one of the plurality of second crests a distance from 50 to 1000 microns.

3. The component of claim 1, wherein the first sinuous slot has a sinusoidal shape.

4. The component of claim 1, wherein the first sinuous slot has a sawtooth shape.

5. The component of claim 1, wherein the plurality of non-intersecting sinuous slots includes a third sinuous slot adjacent to the second sinuous slot, the third sinuous slot including a plurality of third crests and a plurality of third troughs, wherein each of the plurality of second troughs aligns with an adjacent one of the plurality of third crests.

6. The component of claim 5, wherein each of the plurality of third crests aligns with a respective one of the plurality of first crests, and each of the plurality of third troughs align with a respective one of the plurality of first troughs.

7. The component of claim 1, wherein the plurality of non-intersecting sinuous slots define a non-intersecting pattern.

8. The component of claim 1, wherein the first sinuous slot defines a sinuous shape including a plurality of waves, each of the plurality of waves including one of the plurality of first crests and one of the plurality of first troughs.

9. The component of claim 1, wherein the first sinuous slot defines a depth in a range from 100 microns to 1100 microns.

10. The component of claim 1, wherein the first sinuous slot defines an amplitude and a wavelength, and a ratio of the amplitude to the wavelength is in a range from 1:64 to 4:1.

11. A method of forming a ceramic coating for a component, the method comprising:
laying the ceramic coating on a substrate of the component;
removing a first sinuous slot from a surface of the ceramic coating, the first sinuous slot defining a first sinuous shape, the first sinuous shape defining a travel direction and an amplitude direction; and
removing a second sinuous slot from the surface of the ceramic coating such that the second sinuous slot is spaced from the first sinuous slot in a non-intersecting manner, the second sinuous slot defining a second sinuous shape,
wherein the second sinuous slot is shifted along the travel direction from the first sinuous slot.

12. The method of claim 11, wherein the first sinuous shape includes a plurality of waves, each wave including a crest and a trough, wherein the respective troughs of the plurality of waves of the first sinuous slot align with the respective crests of the plurality of waves of the second sinuous slot.

13. The method of claim 11, wherein removing the first sinuous slot further comprises moving a laser along a first sinusoidal path having a first phase, wherein removing the second sinuous slot further comprises moving the laser along a second sinusoidal path having a second phase, wherein the second phase differs from the first phase by approximately 180 degrees.

14. The method of claim 11, wherein removing the first sinuous slot further comprises moving a laser along a first sawtooth path having a first phase, wherein removing the second sinuous slot further comprises moving the laser along a second sawtooth path having a second phase, wherein the second phase differs from the first phase by approximately 180 degrees.

15. The method of claim 11, wherein the first sinuous shape is a different shape than the second sinuous shape.

16. The method of claim 11, wherein the first sinuous shape and the second sinuous shape are a same shape.

17. A ceramic coating for a component, the ceramic coating comprising:
a surface defining a vertical axis and a horizontal axis, and
a plurality of non-intersecting sinuous slots defined in the surface, the plurality of non-intersecting sinuous slots including a first sinuous slot and a second sinuous slot adjacent to the first sinuous slot,
wherein the first sinuous slot defines a plurality of first crests and a plurality of first troughs,
wherein the second sinuous slot defines a plurality of second crests and a plurality of second troughs,
wherein each of the plurality of first troughs of the first sinuous slot aligns with an adjacent one of the plurality of second crests of the second sinuous slot along the vertical axis.

18. The ceramic coating of claim 17, wherein the plurality of non-intersecting sinuous slots includes a third sinuous slot adjacent to the second sinuous slot, the third sinuous slot including a plurality of third crests and a plurality of third troughs, wherein each of the plurality of second troughs aligns with an adjacent one of the plurality of third crests along the vertical axis.

19. The ceramic coating of claim 17, wherein the first sinuous slot has a sinusoidal shape.

20. The ceramic coating of claim 17, wherein the first sinuous slot has a sawtooth shape.
